(19) United States
(12) Patent Application Publication
(10) Pub. No.: US 2021/0309829 A1
(43) Pub. Date: Oct. 7, 2021

(54) CURABLE RESIN COMPOSITION AND MOUNTING STRUCTURE

(71) Applicant: Panasonic Intellectual Property Management Co., Ltd., Osaka (JP)

(72) Inventors: NAOMICHI OHASHI, Hyogo (JP); KOSO MATSUNO, Osaka (JP); YASUHIRO SUZUKI, Osaka (JP)

(21) Appl. No.: 17/274,225

(22) PCT Filed: Oct. 16, 2019
(86) PCT No.: PCT/JP2019/040560

§ 371 Date: Mar. 8, 2021

(30) Foreign Application Priority Data
Nov. 7, 2018 (JP) 2018-209727

(51) Int. Cl. C08K 5/17; C08L 63/00; C08K 5/092; H05K 1/18; H05K 3/34; H05K 3/28

(52) U.S. Cl. CPC C08K 5/17; C08L 63/00; C08K 5/092; B23K 35/262; H05K 3/341; H05K 3/28; H05K 1/181

(57) ABSTRACT

A curable resin composition contains a thermosetting resin, a curing agent, and one or more selected from the group consisting of organic acids, amines, and amine salts, and a percentage of a total amount of the one or more selected from the group with respect to a total mass of the curable resin composition is 0.3% by mass or more and 2.2% by mass or less.

### TECHNICAL FIELD

The present invention relates to a curable resin composition and a mounting structure including a curable resin reinforcing portion made from the curable resin composition and an electronic component mounted on a wire on a board.

### BACKGROUND ART

In the field of electronics, research and development is underway to make electronic devices wearable by integrating electronic devices with clothes or attaching electronic devices to skin, and such wearable electronic devices are being put into practical use. Wearable devices need to be flexible. In that case, there is an increasing need to use flexible materials even for base materials and wire materials that configure circuit boards. Additionally, wearable devices are susceptible to mechanical loads such as drop impacts. Therefore, it is important to ensure the impact resistance reliability of solder joints for base materials and wire materials made of flexible materials.

As a method for enhancing the impact resistance reliability of solder joints, reinforcement of the solder joints with an underfill sealant is performed. In this sealing reinforcement method, after soldering, a gap between a ball grid array (BGA)-type semiconductor package and an electronic circuit board is filled with a reinforcing resin material to fix the BGA-type semiconductor package and the electronic circuit board to each other, thereby relieving stress generated by heat or mechanical impacts and enhancing the impact resistance reliability of joints. As the underfill sealant, an epoxy resin, which is typically a thermosetting resin, is mainly used.

In addition, as another method, proposed is a method in which a solder paste containing a thermosetting resin is used to enhance the impact resistance reliability of joints. In the solder paste containing a thermosetting resin, the contained resin and solder are separated from each other in a step of melting and connecting the solder by heating, whereby a reinforcing structure in which the periphery of the solder is covered with a curable resin composition can be formed. As a result of the reinforcement, it becomes possible to enhance the impact resistance reliability of solder joints (for example, refer to Patent Literature 1).

### CITATION LIST

### Patent Literature

PTL 1: Japanese Patent Unexamined Publication No. 2013-123078

### SUMMARY OF THE INVENTION

According to a first gist of the present invention, provided is a curable resin composition containing a thermosetting resin, a curing agent, and one or more selected from the group consisting of organic acids, amines, and amine salts, in which a percentage of a total amount of the one or more selected from the group with respect to a total mass of the curable resin composition is 0.3% by mass or more and 2.2% by mass or less.

### BRIEF DESCRIPTION OF DRAWINGS

FIG. 1 is a schematic cross-sectional view of a mounting structure which has an electronic component mounted on a wire on a board in one embodiment of the present invention.

### DESCRIPTION OF EMBODIMENT

In the case of enhancing the reliability of a solder joint using an underfill sealant or a solder paste containing a thermosetting resin, a reinforcing portion made from a curable resin composition covers the solder joint. Therefore, in a case where a repair work becomes necessary to remove a component after soldering due to, for example, the inadequacy of the component, a board, and the joint, there is a problem in that the work is difficult to perform. Therefore, in a case where the periphery of a solder joint is surrounded by a curable resin reinforcing portion, it is necessary to reinforce the solder joint with a curable resin composition having excellent repairability.

In a case where a solder joint has been reinforced with a curable resin composition, the easiness of a repair work of removing a component from a board is significantly affected by, in particular, the elastic modulus of the curable resin composition at the time of repairing or the adhesion area of the resin to the component and the board. In addition, it was found that, as the content of organic acids, amines, and amine salts, which are activator components, present in the curable resin composition increases, the glass transition temperature (Tg) lowers, and the elastic modulus of the curable resin composition during repair decreases. A decrease in the elastic modulus of the curable resin composition improves repairability. In addition, the following fact was also found. Organic acids, amines, and amine salts have a function of removing oxide films of solder and thus have an effect of improving the melting property of the solder at the melting point of the solder or higher. As a result, the presence of organic acids, amines, and amine salts improves repairability. However, it is conceivable that, when organic acids, amines, and amine salts are excessively present, an ion component increases, and thus the insulating property (particularly, the hygroscopic insulating property) degrades. Therefore, in order to satisfy both the repairability and the insulating property of the curable resin composition that reinforces the periphery of the solder joint, it is necessary to adjust the amounts of organic acids, amines, and amine salts in an appropriate range.

An object of the present invention is to provide a curable resin composition satisfying both excellent repairability and an excellent insulating property and a mounting structure including a curable resin reinforcing portion made from the curable resin composition and an electronic component mounted on a wire on a board.

Hereinafter, one embodiment of the present invention will be described with reference to drawings, but the present invention is not limited to such an embodiment.

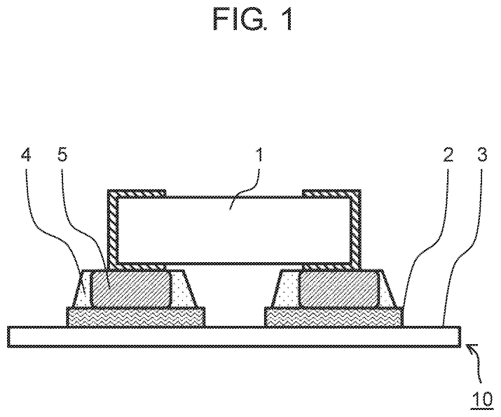

FIG. 1 is a schematic cross-sectional view of a mounting structure which has an electronic component mounted on a wire on a board in one embodiment of the present invention. As shown in FIG. 1, mounting structure 10 includes electronic component 1 having electrodes, board 3 having a plurality of wires 2, solder joints 5 that are each interposed between electronic component 1 and each of wires 2 on board 3 and connect with metal (electrically connect) electronic component 1 and each of wires 2, and curable resin reinforcing portions 4 that reinforce solder joints 5 and are made from a curable resin composition in the embodiment of the present invention. The curable resin composition contains a thermosetting resin, a curing agent, and one or more selected from the group consisting of organic acids, amines, and amine salts (hereinafter, also referred to as organic acids and the like). Curable resin reinforcing portions 4 partially or fully cover solder joints 5 except for the connection portions between solder joints 5 and electronic component 1 and the connection portions between solder joints 5 and wires 2.

Here, the details of each composition of the curable resin composition that configures curable resin reinforcing portions 4 in FIG. 1 and the details of the configuration of mounting structure 10 in the embodiment of the present invention will be further described.

<Curable Resin Composition>

As described above, the curable resin composition contains a thermosetting resin, a curing agent, and one or more selected from the group consisting of organic acids, amines, and amine salts.

In the present disclosure, the “curable resin composition” refers to a composition containing a cured resin and more specifically refers to a composition containing a thermosetting resin in a cured state obtained by performing a heating treatment on a mixture, which serves as a raw material, of an uncured thermosetting resin, an unreacted curing agent, and one or more selected from the group consisting of unreacted organic acids, amines, and amine salts and causing a curing reaction. An “uncured resin composition” refers to a mixture that is preferably liquid at room temperature and contains an uncured thermosetting resin, an unreacted curing agent, and one or more selected from the group consisting of unreacted organic acids, amines, and amine salts. The details of each composition will be described below.

(Thermosetting Resin)

The thermosetting resin refers to a resin that has a predetermined functional group in the structure and can be cured by heating. In the present disclosure, the expression “the curable resin composition contains a thermosetting resin” mainly means that the curable resin composition contains a thermosetting resin cured by crosslinking between molecules by a heating treatment. Here, the thermosetting resin contained in the curable resin composition does not need to be fully cured, and the curable resin composition may contain a thermosetting resin in which some of the molecules are not crosslinked with each other.

As the thermosetting resin, for example, an epoxy resin, an urethane resin, an acrylic resin, a polyimide resin, a polyamide resin, bismaleimide, a phenol resin, a polyester resin, a silicone resin, an oxetane resin, and the like can be exemplified, but the thermosetting resin is not limited thereto. The curable resin composition may contain one thermosetting resin or a combination of two or more thermosetting resins. Among the thermosetting resins, an epoxy resin is preferable in consideration of the improvement in the physical properties of the curable resin composition. As the epoxy resin, for example, a bisphenol A-type epoxy resin, a bisphenol F-type epoxy resin, a bisphenol S-type epoxy resin, a glycidylamine-type resin, an alicyclic epoxy resin, an aminopropane-type epoxy resin, a biphenyl-type epoxy resin, a naphthalene-type epoxy resin, an anthracene-type epoxy resin, a triazine-type epoxy resin, a dicyclopentadiene-type epoxy resin, a triphenylmethane-type epoxy resin, a fluorene-type epoxy resin, a phenol aralkyl-type epoxy resin, a novolac-type epoxy resin, and the like are exemplified.

The content of the thermosetting resin with respect to the total mass of the curable resin composition can be adjusted to an appropriate preferable amount depending on elements such as the type and content of a curing agent described below, the type and content of organic acids and the like, and other additives. For example, the proportion of the thermosetting resin that can be present is 60% by mass or more and 95% by mass or less, preferably 65% by mass or more and 90% by mass or less, and more preferably 70% by mass or more and 90% by mass or less with respect to the total mass of the curable resin composition. In a case where the curable resin composition is applied as, for example, curable resin reinforcing portions 4 that surround the peripheries of solder joints 5, it is possible to make the thermosetting resin present in the curable resin composition in an amount in the above-described range by appropriately adjusting the content of the uncured thermosetting resin with respect to the total mass of a mixture paste when the uncured resin composition is mixed with the powder of solder particles described below. Furthermore, the content of the thermosetting resin in the curable resin composition can also be adjusted by appropriately changing the temperature or the heating time when the mixture paste is applied or printed by a method described below and then heated in a reflow furnace or the like.

(Curing Agent)

As the curing agent, an ordinary curing agent is contained depending on the thermosetting resin. For example, as the curing agent, the curable resin composition may contain one or more compounds selected from the group consisting of an imidazole-based compound, a thiol-based compound, a modified amine-based compound, a polyfunctional phenolic compound, and an acid anhydride-based compound. In the present disclosure, the expression “the curable resin composition contains the curing agent” means that the curable resin composition may contain a curing agent in a reacted state to crosslink and cure the uncured thermosetting resin or may contain a curing agent remaining in an unreacted state. As the curing agent, a preferable curing agent is appropriately selected depending on the conditions and the like for mounting electronic component 1 described below. For example, in a case where low-temperature curing becomes important, an imidazole-based compound is preferable. As the imidazole-based compound, it is possible to use, for example, a commercially available product such as 2E4MZ, 2MZ, C11Z, 2PZ, 2P4MZ, 1B2MZ, 1B2PZ, 2MZ-CN, 2E4MZ-CN, 2PZ-CN, C11Z-CN, 2PZ-CNS, C11Z-CNS, 2MZ-A, C11Z-A, 2E4MZ-A, 2P4MHZ, 2PHZ, 2MA-OK, or 2PZ-OK (all manufactured by Shikoku Chemicals Corporation) or a compound obtained by adding the imidazole-based compound to an epoxy resin. Here, the imidazole-based compound is not limited thereto. In addition, the curable resin composition may also contain a curing agent obtained by coating the above-described curing agent with a polyurethane-based, polyester-based, or other polymer substance or the like and putting the curing agent into a microcapsule.

The content of the curing agent with respect to the total mass of the curable resin composition can be adjusted to an appropriate preferable amount depending on elements such as the type and content of the thermosetting resin described above, the type and content of the organic acids and the like, and other additives. For example, the proportion of the curing agent that can be present is 1% by mass or more and 40% by mass or less, preferably 5% by mass or more and 30% by mass or less, and more preferably 5% by mass or more and 20% by mass or less with respect to the total mass of the curable resin composition. In a case where the curable resin composition is applied as, for example, curable resin reinforcing portions 4 that surround the peripheries of solder joints 5, it is possible to make the curing agent present in the curable resin composition in an amount in the above-described range by appropriately adjusting the content of the unreacted curing agent with respect to the total mass of the mixture paste when the uncured resin composition is mixed with the powder of solder particles described below. Furthermore, the content of the curing agent in the curable resin composition can also be adjusted by appropriately changing the temperature or the heating time when the mixture paste is applied or printed by the method described below and then thermally treated in a reflow furnace or the like.

When the contents of the thermosetting resin and the curing agent with respect to the total mass of the curable resin composition are adjusted to preferable amounts, respectively, it is possible to improve the connection reliability of solder joints 5 when the curable resin composition is used as curable resin reinforcing portions 4 for the mounting of electronic component 1 on wires 2 on board 3.

(Organic Acids, Amines, and Amine Salts)

The types of the organic acids, the amines, and the amine salts are not particularly limited as long as the organic acids, the amines, and the amine salts have an effect of removing metal oxide films. When these components are mixed together with the uncured thermosetting resin and the unreacted curing agent, it is possible to exhibit an excellent flux action, that is, a reduction action of removing an oxide film generated on a metal surface to which the mixture paste, into which the powder of solder particles are further mixed, has been applied and an action of promoting the wettability of solder to a joining metal surface by decreasing the surface tension of molten solder.

The total amount of the organic acids, the amines, and the amine salts with respect to the total mass of the curable resin composition is 0.3% by mass or more and 2.2% by mass or less. The total amount is a proportion of preferably 0.4% by mass or more and 2% by mass or less, more preferably 0.7% by mass or more and 1.5% by mass or less, and still more preferably 0.7% by mass or more and 1.1% by mass or less. When the organic acids, the amines, and the amine salts are present in the curable resin composition in an amount in the above-described range, the curable resin composition is capable of satisfying both excellent repairability and an excellent insulating property and preferably functioning in the case of being applied as curable resin reinforcing portions 4 that surround the peripheries of solder joints 5. In a case where the curable resin composition is applied as, for example, curable resin reinforcing portions 4 that surround the peripheries of solder joints 5, it is possible to make the organic acids and the like present in the curable resin composition in an amount in such a range by appropriately adjusting the total content of the organic acids, the amines, and the amine salts with respect to the total mass of the mixture paste when the uncured resin composition is mixed with the powder of solder particles described below. Furthermore, the content of the organic acids and the like in the curable resin composition can also be adjusted by appropriately changing the temperature or the heating time when the mixture paste is applied or printed by the method described below and then thermally treated in a reflow furnace or the like. This is because the organic acids, the amines, and the amine salts are consumed and decreased by being heated in the reflow furnace or the like at the melting points thereof or higher.

In the present disclosure, the total amount (% by mass) of the organic acids, the amines, and the amine salts with respect to the total mass of the curable resin composition refers to the total amount (% by mass) of the amines and the amine salts that is calculated by immersing the curable resin composition in acetone to extract the organic acids, the amines, and the amine salts and performing a mass analysis on each component of the extraction liquid by gas chromatography mass spectrometry (GC/MS).

As the organic acids, for example, lauric acid, myristic acid, pivalic acid, palmitic acid, and stearic acid, which are saturated aliphatic monocarboxylic acids, crotonic acid, which is an unsaturated aliphatic monocarboxylic acid, oxalic acid, L(−)-malic acid, malonic acid, succinic acid, glutaric acid, glutaric anhydride, dimethylglutaric acid, adipic acid, pimelic acid, suberic acid, azelaic acid, and sebacic acid, which are saturated aliphatic dicarboxylic acid, maleic acid and fumaric acid, which are unsaturated aliphatic dicarboxylic acids, phthalaldehydic acid, phenylbutyric acid, phenoxyacetic acid, and phenylpropionic acid, which are aromatic carboxylic acids, diglycolic acid, which is an ether-based dicarboxylic acid, citric acid, abietic acid, and ascorbic acid, which are other organic acids, and the like can be exemplified. As the amines, for example, diphenyl guanidine, naphthylamine, diphenylamine, triethanolamine, monoethanolamine, and the like can be exemplified. As the amine salts, for example, polyamines such as ethylenediamine, organic acid salts of an amine such as cyclohexylamine, ethylamine, and diethylamine, and the like can be exemplified.

The curable resin composition contains one or more selected from the group consisting of the organic acids, the amines, and the amine salts as described above and may contain the organic acids, the amines, or the amine salts singly or a combination of two or more types thereof. As the one or more selected from the group consisting of organic acids, amines, and amine salts, the curable resin composition preferably contains at least one type of organic acids, amines, or amine salts having a melting point of 51° C. or higher and 120° C. or lower and at least one type of organic acids, amines, or amine salts having a melting point of 15° C. or higher and lower than 51° C. This is because, when containing at least one type of organic acids, amines, or amine salts having a melting point of 15° C. or higher and lower than 51° C., the curable resin composition exhibits a preferable effect for improving the repairability of the curable resin composition.

Hereinafter, the organic acids, amines, or amine salts having a melting point of 51° C. or higher and 120° C. or lower will also be referred to as the first material. As the first material, for example, L(−)-malic acid, glutaric acid, glutaric anhydride, dimethylglutaric acid, diethylamine hydrochloride, and the like can be exemplified. Hereinafter, the organic acids, amines, or amine salts having a melting point of 15° C. or higher and lower than 51° C. will also be referred to as the second material. As the second material, for example, lauric acid, levulinic acid, pivalic acid, phenylbutyric acid, diphenylamine, triethanolamine, and the like can be exemplified.

More preferably, the mass ratio between the first material and the second material is 10×(first material)<(second material)<80×(first material). This is because, in the curable resin composition, the mass of the second material having a lower melting point is significantly larger than the mass of the first material having a higher melting point in the curable resin composition, and, particularly when the mass ratio is adjusted as described above, the curable resin composition exhibits a more preferable effect for improving the repairability of the curable resin composition and also exhibits a more preferable effect for the insulating property.

(Other Components)

The curable resin composition of the present embodiment may further contain other components such as a modifier or an additive as necessary. For example, in the case of being applied as the mixture paste after being further mixed with the powder of solder particles, the curable resin composition may contain an inorganic or organic additive as a viscosity modifier or a thixotropy-imparting agent in order to hold a printed shape on wire 2. For example, as an inorganic additive, the curable resin composition may contain silica, alumina, or the like. As an organic additive, the curable resin composition may contain a solid epoxy resin, a low-molecular-weight amide, polyesters, an organic derivative of castor oil, or the like. For example, cured castor oil or stearic acid amide can be exemplified. The curable resin composition may contain the other component singly or may contain a combination of two or more types of other components.

<Mounting Structure>

Hereinafter, a method for manufacturing mounting structure 10 shown in FIG. 1 will be described.

First, the mixture paste of the powder of solder particles and the uncured resin composition (a mixture containing the uncured thermosetting resin, the unreacted curing agent, and the unreacted organic acids and the like) is prepared. The solder particles are particles substantially made from a solder alloy and may have an oxide film or the like present on the surface in some cases. The alloy composition of the solder alloy is not particularly limited, and it is possible to use, for example, a Sn-based alloy composition. The solder particles may be solder particles having a single type of Sn-based alloy composition or may be a mixture of two or more types of solder particles having mutually different Sn-based alloy compositions. The Sn-based alloy composition may be, for example, at least one alloy composition selected from the group consisting of an Sn—Bi-based composition, an Sn—In-based composition, an Sn—Bi—In-based composition, an Sn—Ag-based composition, Sn—Cu-based composition, an Sn—Ag—Cu-based composition, an Sn—Ag—Bi-based composition, an Sn—Cu—Bi-based composition, an Sn—Ag—Cu—Bi-based composition, an Sn—Ag—In-based composition, an Sn—Cu—In-based composition, an Sn—Ag—Cu—In-based composition, and an Sn—Ag—Cu—Bi—In-based composition. More specifically, the Sn-based alloy composition may be preferably 42Sn-58Bi, 42Sn-57Bi-1.0Ag, 16Sn-56Bi-28In, 255n-55Bi-20In, or the like. However, the alloy composition can be appropriately selected mainly in consideration of the heat resistance of a member to be joined that should be soldered. According to mounting structure 10 in the present embodiment, the members to be joined can be wires 2 and electronic component 1.

In the present disclosure, the melting point of the solder particles means a temperature where a sample of the solder particles is admitted to begin melting at the time of observing a change in the state of the sample of the solder particles in a heating and temperature-rising process and can be measured using the differential scanning calorimeter (DSC), TG-DTA, or the like. The above description is also true for the melting point of solder joint 5, and the melting point of solder joint 5 is determined by measuring the melting point of the solder particles that configure the joint.

The alloy composition of the solder particles in the present disclosure will be expressed by connecting the element symbols of elements contained in the solder particles with a hyphen. In the present disclosure, there will be a case where a numerical value or a numerical range is shown immediately before a metal element to describe an alloy composition of the solder particles, and, in this case, the numerical value or the numerical range indicates the mass percentage of each element in the alloy composition as is typically used in the corresponding technical field. The solder particles may contain a small amount of metal that is inevitably mixed such as Ni, Zn, Sb, or Cu as long as the solder particles are substantially made up of the listed elements.

An example of the method for applying or printing the mixture paste prepared as described above onto wires 2 on board 3 will be described in detail.

Wire 2 may contain, for example, conductive Ag. More specifically, wire 2 can be formed by, for example, printing or applying a conductive wire paste containing metal such as Ag, Cu, Ni, Au, or Sn onto board 3 in a predetermined pattern and drying the conductive wire paste. In addition, as such a wire paste, a commercially available product, for example, Ag paste XA3512 manufactured by Fujikura Kasei Co., Ltd., which is used in examples described below, may be used as it is.

As board 3, any board may be used as long as the board allows wires 2 to be formed thereon and functions as a board on which electronic component 1 can be mounted. Examples of the material of board 3 include materials made of a thermoplastic resin (for example, polyethylene terephthalate (PET), vinyl chloride (PVC), polyethylene, polyimide, polyurethane, polyester, vinyl acetate, or polyvinyl butyral) or the like. Mounting structure 10 according to the present embodiment includes curable resin reinforcing portions 4 and thus has not only high impact resistance reliability of solder joints 5 but also excellent repairability and an excellent insulating property. Therefore, mounting structure 10 according to the present embodiment can be preferably applied to wearable devices requiring flexibility. Furthermore, in a case where a thermoplastic resin is used for board 3 in order for a subsequent reflow step, the melting point of the alloy for the powder of the solder particles needs to be lower than the melting point of board 3. For example, the powder of the solder particles (solder joints 5 to be formed afterwards) can be formed of an alloy that may contain Sn and Bi and has a melting point of 130° C. or lower.

The method for applying a wire material onto board 3 is not particularly limited, and any conventionally well-known method may be used. Examples thereof include a screen printing method, an offset printing method, an inkjet printing method, a flexographic printing method, a gravure printing method, stamping, dispensing, squeegee printing, silk screen printing, spraying, brush application, coating, and the like. The method for drying the wire material is also not particularly limited, and any conventionally well-known method may be used.

Electronic component 1 may be a component for surface mounting (SMT (surface mount technology)). Examples of such electronic component 1 include a chip component, a semiconductor component, and the like. The chip component may be, for example, a chip resistance component, a capacitor, or the like. In addition, as the semiconductor component, it is possible to use a semiconductor package such as CSP or BGA formed by providing a solder ball as a terminal or QFP formed by providing a lead as a terminal, a semiconductor element (bare chip) formed by providing a terminal without being housed in a package, or the like.

First, the above-described mixture paste is applied to a predetermined region on wires 2 on board 3, that is, electrode regions to which electrodes of electronic component 1 should be joined (which can also be referred to as “lands”). The mixture paste can be applied by, for example, a method such as screen printing where a metal mask having through holes at positions corresponding to the electrode regions is placed on board 3 on which wires 2 are formed, then, the mixture paste is supplied to the surface of the metal mask, and the through holes are filled with the mixture paste using a squeegee. After that, the metal mask is peeled off, whereby board 3 including wires 2 coated with the mixture paste in each of the electrode regions can be obtained.

After that, while the mixture paste remains uncured, electronic component 1 is disposed on wires 2 on board 3 using, for example, a chip mounter or the like such that the electrodes (for example, the terminals) of electronic component 1 and the electrode regions on wires 2 face each other through the mixture paste.

In this state, board 3 having electronic component 1 disposed on wires 2 is heated to the melting point of the solder particles in the mixture paste or higher according to a predetermined temperature profile, for example, in a reflow furnace to melt the powder of the solder particles. As a result, the molten solder spreads to wet the electrodes of electronic component 1 and wires 2 on board 3. At the same time, the solder in the mixture paste and the resin composition separate from each other. The heating temperature in the reflow furnace can be set to an appropriate temperature at which the solder particles are sufficiently melted and the curing reaction of the resin component sufficiently proceeds. This heating temperature can be preferably set such that the curing reaction of the thermosetting resin proceeds before the powder of the solder particles is completely melted and the aggregation and melting of the solder particles are not hindered. In addition, the heating temperature and the heating time in the reflow furnace are also adjusted such that the total amount of the organic acids, the amines, and the amine salts with respect to the total mass of the curable resin composition falls within the above-described range. The separated and cured curable resin composition is positioned around the molten solder as curable resin reinforcing portions 4. After that, when the temperature decreases to the melting point of the solder or lower, the solder solidifies to form solder joints 5, and the electrodes of electronic component 1 and wires 2 of board 3 are electrically connected to each other.

Mounting structure 10 in which electronic component 1 is mounted on wires 2 on board 3 and solder joints 5 in which electronic component 1 and wires 2 are joined to each other with metal and curable resin reinforcing portions 4 that surround the peripheries of solder joints 5 and are made from the curable resin composition are provided as shown in FIG. 1 is manufactured as described above.

### EXAMPLE

In order to evaluate the curable resin composition according to the embodiment of the present invention, the repairability and the insulating property of a mounting structure in which an electronic component, specifically, a chip resistance component was joined to wires on a board using a mixture paste (a mixture of the powder of solder particles and an uncured resin composition) were evaluated. Hereinafter, examples and comparative examples will be described. The following forms of the examples and the comparative examples of the present invention are merely examples and do not limit the present invention in any way. In the examples and the comparative examples, “parts” and “%” are mass-based unless otherwise described.

<Materials for Mixture Paste Containing Uncured Resin Composition and Preparation Method Thereof>

As a thermosetting resin, 806 manufactured by Mitsubishi Chemical Corporation, which is a bisphenol F-type epoxy resin, was used. Furthermore, in order to remove a metal oxide film on solder particles, in each of Examples 1 to 11 and Comparative Examples 1 to 10, two materials were selected and used from glutaric acid (melting point: 98° C.) and levulinic acid (melting point: 32° C.) as organic acids, triethanolamine (melting point: 21° C.) as amines, and diethylamine hydrochloride (melting point: 108° C.) as amine salts. Here, as the two materials, either glutaric acid or diethylamine hydrochloride having a melting point of 51° C. or higher and 120° C. or lower was selected as a first material, and either levulinic acid or triethanolamine having a melting point of 15° C. or higher and lower than 51° C. was selected as a second material. As a curing agent, 2E4MZ manufactured by Shikoku Chemicals Corporation, which is an imidazole-based curing agent, was used. As a viscosity modifier, THIXCIN R manufactured by Elementar Japan Co., Ltd., which is a castor oil-based thixotropic agent, was used.

As the solder particles, spherical particles having a solder alloy composition of 25Sn-55Bi-20In were used. The solder particles had an average particle size of 25 μm and a melting point (MP) of 96° C.

For example, in Example 1, first, with respect to 100 parts by mass of the powder of the solder particles to be added afterwards, 0.5 parts by mass of the castor oil-based thixotropic agent was added to 20 parts by mass of the bisphenol F-type epoxy resin, and the castor oil-based thixotropic agent was dissolved by being heated and stirred at 120° C. After that, the caster oil-based thixotropic agent was cooled in the air to room temperature. 3 parts by mass of the imidazole-based curing agent, 3 parts by mass of glutaric acid, and 3 parts by mass of levulinic acid were added to the castor oil-based thixotropic agent, kneaded with a vacuum planetary mixer for 10 minutes, and uniformly dispersed in an epoxy resin, thereby obtaining an uncured resin mixture. One hundred parts by mass of the powder of the solder particles was further added to this uncured resin mixture and kneaded with the vacuum planetary mixer for 30 minutes, thereby obtaining a mixture paste. In Examples 2 to 11 and Comparative Examples 1 to 10, the types and the blending amounts of the organic acids, the amines, and the amine salts to be added were adjusted and appropriately changed in consideration of the reflow temperatures and the reflow times in the subsequent step so as to satisfy individual values with respect to the total mass of the curable resin composition after reflow, which are summarized in Table 1 below.

<Evaluation of Repairability and Insulating Property>

(Evaluation of Repairability)

Using the mixture paste prepared as described above, a chip resistance component was mounted on a board on which wires had been formed using a wire material, thereby producing a mounting structure. As the wire material,

Ag paste XA3512 manufactured by Fujikura Kasei Co., Ltd. was used. The wire material was applied onto a PET film that was the board and dried at 120° C. for 15 minutes, thereby forming electrodes corresponding to the electrode sizes in the chip resistance component having a 3216 size (a size of 3.2 mm×1.6 mm) and wires connected from the electrodes.

Next, the mixture paste of each of Examples 1 to 11 and Comparative Examples 1 to 10 was printed on the electrodes on the wires. On the board on which the wires were formed through a 0.1 mm-thick metal mask in accordance with the wire sizes in the electrodes for the chip resistance component having the 3216 size. In addition, the chip resistance component having the 3216 size was mounted on the prints and passed through, for example, a reflow furnace set to 125° C. in Example 1 for 10 minutes, thereby completely joining the chip resistance component. In Examples 2 to 11 and Comparative Examples 1 to 10, the reflow temperatures and the reflow times were adjusted in consideration of the types and the blending amounts of the organic acids, the amines, and the amine salts that had been added to the mixture paste so as to satisfy individual values with respect to the total mass of the curable resin composition after reflow in Table 1 shown below.

The board in the mounting structure for repairability evaluation of each of Examples 1 to 11 and Comparative Examples 1 to 10 produced as described above was heated on a hot plate set at 130° C. for one minute. After that, the end of the chip resistance component was pinched with a tweezer, and the chip resistance component was pulled up straight. A case where the time taken to remove the chip resistance component was 10 seconds or shorter was evaluated as A, a case where the time was 11 seconds to 20 seconds was evaluated as B, and a case where the time was 21 seconds or longer was evaluated as C. The grade A was regarded as pass, but the grades B and C were regarded as fail since the curable resin composition was not suitable for use. The evaluation results are summarized in Table 1 below.

(Evaluation of Insulating Property)

The prepared mixture paste of each of Examples 1 to 11 and Comparative Examples 1 to 10 was printed on the electrodes through a 0.1 mm metal mask using a comb-shaped board (electrode width: 0.3 mm, electrode spacing: 0.3 mm) described in JIS type 2. After that, the printed mixture paste was passed through, for example, a reflow furnace set to 125° C. in Example 1 for 10 minutes, thereby producing an evaluation board. In Examples 2 to 11 and Comparative Examples 1 to 10, the reflow temperatures and the reflow times were adjusted in consideration of the types and the blending amounts of the organic acids, the amines, and the amine salts that had been added to the mixture paste so as to satisfy individual values with respect to the total mass of the curable resin composition after reflow in Table 1 shown below. While a direct current voltage of 50 V was applied to the comb-shaped electrode board in a constant temperature and humidity chamber at 85° C. and 85% RH for up to 1000 hours, the resistance value was continuously measured on a steady basis. A case where the resistance value was 10 to the power of 6 or more was evaluated as A (pass), and a case where the resistance value was lower than 10 to the power of 6 was evaluated as C (fail). The evaluation results are summarized in Table 1 below.

<Calculation of Values of Contents with Respect to Total Mass of Curable Resin Composition After Reflow>

Regarding the contents (% by mass) of the final first material (either glutaric acid or diethylamine hydrochloride) and the final second material (either levulinic acid or triethanolamine) with respect to the total mass of the curable resin composition after reflow and the total amount (% by mass) of the organic acids, the amines, and the amine salts (that is, the total amount of the first material and the second material) with respect to the total mass of the curable resin composition after reflow in Examples 1 to 11 and Comparative Examples 1 to 10, each of the curable resin compositions after reflow was immersed in acetone and extracted, a mass analysis was performed on each component in the extraction liquid by gas chromatography mass spectrometry (GC/MS), and the content (% by mass) of each component with respect to the total mass of the curable resin composition after reflow was calculated.

Table 1 below shows the first material (either glutaric acid or diethylamine hydrochloride) added in Examples 1 to 11 and Comparative Examples 1 to 10 and the content (% by mass) thereof with respect to the total mass of the curable resin composition after reflow, the second material (either levulinic acid or triethanolamine) added and the content (% by mass) thereof with respect to the total mass of the curable resin composition after reflow, the total amount (% by mass) of the organic acids, the amines, and the amine salts (that is, the total amount of the first material and the second material) with respect to the total mass of the curable resin composition after reflow, and the results of each evaluation.

TABLE 1

| | | | Total amount of | | |
|---|---|---|---|---|---|
| | | | organic acids, | | |
| | Content of first | Content of second | amines, and amine | | |
| | material with | material with | salts with respect | | |
| | respect to total | respect to total | to total mass of | | |
| | mass of curable | mass of curable | curable resin | | Result of |
| | resin composition | resin composition | composition after | Result of | insulating |
| | after reflow | after reflow | reflow | repairability | property |
| Example 1 | Glutaric acid | Levulinic acid | 1.1 | A | A |
| | 0.05 (% by mass) | 1.05 (% by mass) | (% by mass) | | |
| Example 2 | Glutaric acid | Levulinic acid | 1.5 | A | A |
| | 0.1 (% by mass) | 1.4 (% by mass) | (% by mass) | | |
| Example 3 | Glutaric acid | Levulinic acid | 2.2 | A | A |
| | 0.1 (% by mass) | 2.1 (% by mass) | (% by mass) | | |
| Example 4 | Glutaric acid | Levulinic acid | 0.7 | A | A |
| | 0.05 (% by mass) | 0.65 (% by mass) | (% by mass) | | |
| Example 5 | Glutaric acid | Levulinic acid | 0.3 | A | A |
| | 0.02 (% by mass) | 0.28 (% by mass) | (% by mass) | | |
| Example 6 | Diethylamine | Levulinic acid | 1.1 | A | A |
| | hydrochloride | 1.05 (% by mass) | (% by mass) | | |
| | 0.05 (% by mass) | | | | |
| Example 7 | Diethylamine | Levulinic acid | 0.7 | A | A |
| | hydrochloride | 0.65 (% by mass) | (% by mass) | | |
| | 0.05 (% by mass) | | | | |
| Example 8 | Glutaric acid | Triethanolamine | 1.1 | A | A |
| | 0.05 (% by mass) | 1.05 (% by mass) | (% by mass) | | |
| Example 9 | Glutaric acid | Triethanolamine | 0.7 | A | A |
| | 0.05 (% by mass) | 0.65 (% by mass) | (% by mass) | | |
| Example 10 | Diethylamine | Triethanolamine | 1.1 | A | A |
| | hydrochloride | 1.05 (% by mass) | (% by mass) | | |
| | 0.05 (% by mass) | | | | |
| Example 11 | Diethylamine | Triethanolamine | 0.7 | A | A |
| | hydrochloride | 0.65 (% by mass) | (% by mass) | | |
| | 0.05 (% by mass) | | | | |
| Comparative | Glutaric acid | Levulinic acid | 0.25 | B | A |
| Example 1 | 0.02 (% by mass) | 0.23 (% by mass) | (% by mass) | | |
| Comparative | Glutaric acid | Levulinic acid | 0.1 | C | A |
| Example 2 | 0.095 (% by mass) | 0.005 (% by mass) | (% by mass) | | |
| Comparative | Glutaric acid | Levulinic acid | 2.4 | A | C |
| Example 3 | 2.25 (% by mass) | 0.15 (% by mass) | (% by mass) | | |
| Comparative | Glutaric acid | Levulinic acid | 3.0 | A | C |
| Example 4 | 2.8 (% by mass) | 0.2 (% by mass) | (% by mass) | | |
| Comparative | Diethylamine | Levulinic acid | 0.1 | C | A |
| Example 5 | hydrochloride | 0.005 (% by mass) | (% by mass) | | |
| | 0.095 (% by mass) | | | | |
| Comparative | Diethylamine | Levulinic acid | 2.4 | A | C |
| Example 6 | hydrochloride | 0.15 (% by mass) | (% by mass) | | |
| | 2.25 (% by mass) | | | | |
| Comparative | Glutaric acid | Triethanolamine | 0.1 | C | A |
| Example 7 | 0.095 (% by mass) | 0.005 (% by mass) | (% by mass) | | |
| Comparative | Glutaric acid | Triethanolamine | 2.4 | A | C |
| Example 8 | 2.25 (% by mass) | 0.15 (% by mass) | (% by mass) | | |
| Comparative | Diethylamine | Triethanolamine | 0.1 | C | A |
| Example 9 | hydrochloride | 0.005 (% by mass) | (% by mass) | | |
| | 0.095 (% by mass) | | | | |
| Comparative | Diethylamine | Triethanolamine | 2.4 | A | C |
| Example 10 | hydrochloride | 0.15 (% by mass) | (% by mass) | | |
| | 2.25 (% by mass) | | | | |

It was found from the comparison between Examples 1 to 11 and Comparative Examples 1 to 10 that the total amount (mass %) of the organic acids, the amines, and the amine salts with respect to the total mass of the curable resin composition after reflow, the repairability, and the insulating property have a relationship with each other. Specifically, it was found that, when the total amount of the organic acids, the amines, and the amine salts with respect to the amount of the entire curable resin after reflow is in a range of 0.3% by mass or more and 2.2% by mass or less, both the repairability and the insulating property are evaluated as A (pass).

In detail, in a case where the total amount of the organic acids, the amines, and the amine salts with respect to the amount of the entire curable resin after reflow is 0.3% by mass or more, the repairability is evaluated as favorable. The reason therefor is that the organic acids, the amines, and the amine salts act as plasticizing components, lower the glass transition temperature Tg of the thermosetting resin, and lower the elastic modulus particularly at a temperature of 130° C. during repair. Furthermore, since the addition of the organic acids, the amines, and the amine salts removes the oxide film on the joints and promotes the melting of the solder, the repairability improves. The organic acids, the amines, and the amine salts having a melting point in a range of 15° C. or higher and lower than 51° C. (levulinic acid and triethanolamine in Table 1) become active from a low temperature range and are thus more effective for improving repairability to be more favorable. In Comparative Example 1, since the total amount of the organic acids, the amines, and the amine salts was 0.25% by mass, which is below 0.3% by mass, the repairability was evaluated as not favorable and B.

On the other hand, regarding the evaluation of the insulating property, since the organic acids, the amines, and the amine salts become ion components, when the amount thereof is too large, the insulating property degrades. Specifically, the evaluation results show that, when the total amount of the organic acids, the amines, and the amine salts is larger than 2.2% by mass with respect to the amount of the entire curable resin, the insulating property is not suitable for use and is evaluated as fail. For example, in Comparative Example 3, since the total amount thereof was 2.4% by mass, which is above 2.2% by mass, the insulating property was evaluated as fail.

As described above, the range of the total amount of the organic acids, the amines, and the amine salts with respect to the amount of the entire curable resin, which is for the composition to satisfy both excellent repairability and an excellent insulating property, is 0.3% by mass or more and 2.2% by mass or less. In addition, as described above, the organic acids, the amines, and the amine salts having a melting point of 15° C. or higher and lower than 51° C. are particularly effective for improvement in repairability. Therefore, it is found that, when the organic acids, the amines, or the amine salts having a melting point of 51° C. or higher and 120° C. or lower are used as the first material, and the organic acids, the amines, or the amine salts having a melting point of 15° C. or higher and lower than 51° C. are used as the second material, it is more desirable from the viewpoint of the repairability that the ratio between the respective contents of the first material and the second material satisfies 10×(first material)<(second material)<80×(first material). That is, the content of the second material in the curable resin composition is desirably larger than the content of the first material in the curable resin composition by 10 times and smaller than the content of the first material in the curable resin composition by 80 times.

According to the first gist of the present invention, provided is a curable resin composition containing a thermosetting resin, a curing agent, and one or more selected from the group consisting of organic acids, amines, and amine salts, in which a total amount of the one or more selected from the group consisting of organic acids, amines, and amine salts is 0.3% by mass or more and 2.2% by mass or less with respect to a total mass of the curable resin composition.

According to one aspect of the first gist of the present invention, the one or more selected from the group consisting of organic acids, amines, and amine salts may contain a first material having a melting point of 51° C. or higher and 120° C. or lower and a second material having a melting point of 15° C. or higher and lower than 51° C.

According to one of the above-described aspects of the first gist of the present invention, a content of the second material may be larger than a content of the first material by 10 times and smaller than the content of the first material by 80 times.

According to a second gist of the present invention, provided is a mounting structure which has an electronic component mounted on a wire on a board, the mounting structure including a solder joint in which the electronic component and the wire are joined to each other with metal, and a curable resin reinforcing portion that is made from the curable resin composition of the first gist of the present invention and reinforces the solder joint, in which the solder joint is formed of an alloy containing Sn and Bi and having a melting point of 130° C. or lower.

According to one aspect of the second gist of the present invention, a material of the board may be a thermoplastic resin.

According to one aspect of the second gist of the present invention, the wire may contain Ag.

According to the curable resin composition of the present invention, provided is a mounting structure in which excellent repairability and an excellent insulating property are both satisfied and an electronic component is mounted on a wire on a board including a curable resin reinforcing portion made from the curable resin composition.

### INDUSTRIAL APPLICABILITY

According to the curable resin composition of the present invention, excellent repairability and an excellent insulating property, particularly, an excellent moisture-resistant insulating property are both satisfied. When the periphery of a solder joint is surrounded and reinforced with a curable resin reinforcing portion made from the curable resin composition, it is possible to mount an electronic component on a wire on a board, and preferable use in flexible electronic devices such as wearable devices that are used in a state of being attached to clothes or skin is assumed.

### REFERENCE MARKS IN THE DRAWINGS

1 electronic component

2 wire

3 board

4 curable resin reinforcing portion

5 solder joint

10 mounting structure

1. A curable resin composition comprising:
a thermosetting resin;
a curing agent; and
one or more selected from the group consisting of organic acids, amines, and amine salts,
wherein a percentage of a total amount of the one or more selected from the group with respect to a total mass of the curable resin composition is 0.3% by mass or more and 2.2% by mass or less.

2. The curable resin composition of claim 1,
wherein the one or more selected from the group consisting of organic acids, amines, and amine salts include a first material having a melting point of 51° C. or higher and 120° C. or lower and a second material having a melting point of 15° C. or higher and lower than 51° C.

3. The curable resin composition of claim 2,
wherein a content of the second material is larger than a content of the first material by 10 times and smaller than the content of the first material by 80 times.

4. A mounting structure which has an electronic component mounted on a wire on a board, the mounting structure comprising:
a solder joint in which the electronic component and the wire are joined to each other with metal; and
a curable resin reinforcing portion that is made from the curable resin composition according to claim 1 and reinforces the solder joint,
wherein the solder joint is formed of an alloy containing Sn and Bi and having a melting point of 130° C. or lower.

5. The mounting structure of claim 4,
wherein a material of the board is a thermoplastic resin.

6. The mounting structure of claim 4 or 5,
wherein the wire contains Ag.
